(19) United States
(12) Patent Application Publication
(10) Pub. No.: US 2005/0224958 A1
(43) Pub. Date: Oct. 13, 2005

(54) Hard metal substrate body and method for producing the same

(76) Inventors: Dieter Kassel, Witten (DE); Werner Daub, Koln (DE); Klaus Dreyer, Essen (DE); Klaus Rodiger, Bochum (DE); Walter Lengauer, Vienna (AT); Mariann Lovonyak, Vienna (AT); Vera Ucakar, Vienna (AT)

Correspondence Address: THE FIRM OF KARL F ROSS, 5676 RIVERDALE AVENUE, PO BOX 900, RIVERDALE (BRONX), NY, 10471-0900, US

(21) Appl. No.: 10/517,669

(22) PCT Filed: Jun. 4, 2003
(86) PCT No.: PCT/DE03/01834

§ 371 Date: Jun. 2, 2005

(30) Foreign Application Priority Data
Jun. 10, 2002 (DE) 102 25 521.0

(51) Int. Cl. H01L 23/043

(52) U.S. Cl. 257/708

(57) ABSTRACT

The invention relates to a hard metal substrate body consisting of a WC hard material phase and between 3 and 25 mass % of a binding phase containing at least one binding metal Fe, Co and/or Ni, and up to 15 mass % (in relation to the binding phase) of dissolved dopants from the group containing Al, Cr, Mo, Ti, Zr, Hf, V, Nb, Ta. The invention also relates to a method for producing one such hard metal substrate body, using powder metallurgy followed by sintering. According to the invention, the percentage of all of the dopants in the hard metal is limited to a maximum of 4 mass %, the proportion of cubic phase in the hard metal is less than 4 vol. %, and the binding metal content in an edge region of the hard metal substrate body falls from up to 1 μm, preferably up to 0.5 μm, to less than half the binding agent content inside the substrate body. In order to produce said hard metal substrate body, once the eutectic has been reached and at the latest once the sintering temperature has been reached in the heating phase, the vacuum or inert gas atmosphere is replaced by a N₂ atmosphere and maintained at least until the sintering temperature is reached.

The invention relates to a hard metal substrate body comprised of a WC [tungsten carbide] hard material phase and a 3 to 25 mass % [weight %] binder phase which apart from at least one of the binder metals Fe, Co and/or Ni also contains up to 15 mass % (in relation to the binder phase) of dissolved doping agent [dopant] deriving from the group of Al, Cr, Mo, Ti, Zr, Hf, V, Nb and Ta.

The invention relates further to a method whereby the starting mixture for such a hard metal substrate body is pretreated in a powder metallurgical procedure and preprocessed to a green body and the green body is then heated and sintered in an atmosphere in a furnace.

In the mentioned hard metal composition, the doping which is usually in the form of carbides, nitrides or carbonitrides of the elements Ti, Zr, Hf, V, Ta or alloys of these elements, especially Ti₂AlN or Ti₂AlC is supplied to the starting powder mixture as grain-growth blockers which ensure that the WC—Co base alloy remains fine grained and uniform to ensure an optimal hardness and wear resistance.

It has also been long known that the wear characteristics of hard metal bodies can be influenced by the application of one or more surface layers of carbides, nitrides, carbonitrides, borides and/or oxides or of diamond. Even earlier, namely in DE-A 24 33 737 or DE-A 25 25 185 chemical or physical coating processes have been described.

In DE 27 17 842 A1 it has been indicated that a separate process step can be spared if the application of a layer by means of CVD or PVD is provided, whereupon the hard metal body after finish sintering at high temperatures is subjected to a pressure between 2 bar (2×10⁶ Pa) and 5000 bar (5×10⁸ Pa) under a nitrogen containing atmosphere. The treatment temperature should lie between 800° C. and an upper limit which lies at least 50° C. below the maximum sintering temperature. With the resulting surface nitrification which is effective to a depth of 300 μm, an improved wear property as well as an improved oxidation resistance are obtained and a reduction in the diffusion and tendency to adhesion of the hard metal is ensured during interaction with a wear partner. For many practical purposes, however, as before, a surface coating could not be avoided. Especially in the case of diamond coatings, but also with coatings of other compositions, the problem of poor adhesion of the coating to the substrate remains.

The origin of poor adhesion is for example an excessive binder content at the substrate surface.

In DE 199 22 059, a hard metal body or cermet body has been proposed with a hard material phase of WC and/or at least one carbide, nitride, carbonitride and/or oxicarbonitride of at least one of the elements of group IVa, Va or VIa of the periodic system and a binder metal phase of Fe, Co and/or Ni whose proportion amount is 3 to 25 mass % and in which WC crystallites project from the body surface by about 2 to 20 μm. This should be achieved in that a nitrogen-free mixture of hard materials and binder metals are prepressed to a green blank and in a vacuum or inert gas atmosphere is heated to a temperature lying between 1200° C. and the sintering temperature, after which and at the latest upon reaching the sintering temperature, at least intermittently, a nitrogen and optionally carbon-containing atmosphere is established with a pressure between 10³ and 10⁷ Pa, then the body is optionally heated to the sintering temperature and this is maintained for a duration of at least 20 minutes, only a minor cooling down at a rate at a maximum of 2° C. per minute is permitted and following this period the body is cooled. During the heating up or at the latest after reaching the sintering temperature, the nitrogen atmosphere which has been established is maintained until the body in the cool down phase reaches at least 1000° C.

Alternatively thereto, a mixture of hard materials and binder metals containing at least 0.2 mass % nitrogen is prepressed and the resulting green blank is heated to the sintering temperature and during the heating up, an inert gas or vacuum atmosphere is provided until a temperature is reached between 1200° C. and the sintering temperature, whereupon at least intermittently, nitrogen-containing gases are admitted to replace the original atmosphere and provide a pressure of 10³ to 10⁷ Pa. The sintering duration amounts to at least 30 minutes. By the heating up to 1200° C. or later, the nitrogen pressure is maintained in the furnace atmosphere until cooling through at least 1000° C.

The aforementioned method requires a hard material composition which requires the presence of significant amounts, apart from tungsten carbide and the binder, of further carbides, nitrides, carbonitrides.

It is the object of the present invention to provide an improved, substantially two-phase hard metal body of the type described at the outset and a method of making same which by comparison to the known substrate bodies according to the state of the art has an improved adhesion for surface coatings which are deposited from the gas phase. Such coatings can for example be composed of diamond, amorphous carbon, cubic boron nitride, carbon nitrides, oxides as well as metallic hard materials of carbides, nitrides, carbonitrides and oxicarbonitrides, especially of the elements of groups IVa-VIa of the periodic system.

This object is achieved with the hard metal substrate body according to claim 1 in which, according to the invention the sum of the binder metals relative to the substrate body falls off over a depth from 0 to 1 μm to less than half the concentration of the binder metal in the interior of the substrate body. The percentage proportion of the doping agents in the hard metal, which is comprised of tungsten carbide and a binder phase, is limited to 4 mass % according to the invention. Also limited is the percentage proportion of a third cubic phase to a possible maximum of 4 volume %.

In contradistinction to the hard metal bodies obtained in accordance with the state of the art, there is not only a simple depletion of the binder in a boundary zone close to the surface, but a boundary zone in which the “free space” obtained by the binder depletion can also be “filled” by the dopant. The amount of the dopant should however be limited to 15 mass % with reference to the binder metal phase which in turn should make up 3 mass % to 25 mass % of the total. The balance, namely, 75 to 97 mass % is comprised of the pure tungsten carbide hard material phase. Preferably the concentration of the binder phase in the above mentioned region proximal to the surface gradually decreases while the concentration of the dopant, the carbon and the nitrogen greatly increases.

According to a further feature of the invention, the grain size of the tungsten carbide in the hard metal substrate body is a maximum of 1.5 μm.

The layers [coatings] which are especially suitable for the purposes described for hard metal substrate bodies are layers of diamond, but also of the carbides, nitrides and/or carbonitrides of titanium, zirconium and/or hafnium or of Al₂O₃, HfO₂, ZrO₂, mixtures of oxides, amorphous carbon, cubic boron nitrides or carbon nitrides.

Preferably the body is enriched with nitrides and metallic doping agents, for example titanium nitride, chromium nitride or vanadium nitride, in the boundary zone close to the surface.

To produce the hard meal substrate body according to the invention, the method according to claim 6 or the method according to claim 7 is used.

In the first alternative, the starting powder mixture with the desired hard metal composition is pretreated powder-metallurgically in a manner known from the state of the art to a green body by prepressing and heating to the sintering temperature, whereby in the heating phase after the eutectic is reached, but at the latest after reaching the sintering temperature, the vacuum or the inert gas atmosphere is replaced by a N₂ atmosphere with N₂ pressure ≦10⁵ Pa at least by the time the sintering temperature is reached or by the time the end of the retention time is reached, in which the body is maintained at the sintering temperature.

Alternatively thereto it is also possible to undertake the nitrogen treatment after the finish sintering and indeed such that the finish-sintered body is treated below the eutectic temperature with a N₂ atmosphere at a pressure p of 10⁵ Pa <p<10⁷ Pa for at least 10 minutes. This treatment can either be effected in the cooling phase after sintering or in a second step optionally in conjunction with a grinding treatment and/or a blast or jet treatment of the finish-sintered body.

The nitrogen atmosphere can be created either by admitting nitrogen gas into the furnace atmosphere or by introducing precursors, that is nitrogen-containing gases, from which the nitrogen is formed in situ at the corresponding temperature in the gas atmosphere.

It is generally known that the size of the tungsten carbide crystals can be influenced by the duration and the gas composition in which the body to be sintered is maintained at the eutectic temperature. Longer treatment times give rise to larger tungsten carbide crystals.

In a preferred embodiment, the body is heated to 1250° C. and held at this temperature for a duration of at least 20 minutes before the heating up to the sintering temperature is continued. Furthermore, preferably the body is heated initially in the heating up phase, in vacuum and first upon reaching about 1250° C. in an inert gas atmosphere, for example of argon, up to sintering temperature. At the latter a nitrogen atmosphere is created with a pressure of at least 10⁴ Pa. Preferably the heating rate and the cooling rate are at a maximum of 10° C. per minute and preferably each of these rates lie between 2° C. per minute and 5° C. per minute.

According to a further feature of the invention, the starting mixture can contain additives in an amount up to 15 mass % of the binder phase in the form of carbides, nitrides, carbonitrides of the elements from groups IVa, Va and VIa of the periodic system or of aluminum or complex carbides, complex nitrides and/or complex carbonitrides of the form Ti₂AlC, Ti₂AlN, Cr₂AlN, Cr₂AlC, preferably however only in such a quantity which is maximally soluble in the binder phase. These solubility limits are determined from the sum of the dissolved elements and can for each element be altered by the addition of other soluble elements.

In the aforedescribed treatment of the sinter body in a nitrogen atmosphere under a pressure of 10² Pa to 10⁷ Pa the dopant or its carbides, nitrides or carbonitrides diffuse in the direction of the substrate surface and displace by enrichment corresponding hard material particles which is reinforced by the combination of the nitrogen provided and at least one of the metals, in the deeper region of the binder phase and which is depleted at the surface.

The nitrogen treatment is effective because nitrogen dissolves in the binder phase and also affects the carbon activity which also influences the separation of the hard phases. As a result the hard phase enrichment in the surface region can be controlled.

The invention is described in greater detail in the following in connection with exemplary embodiments.

The drawing shows

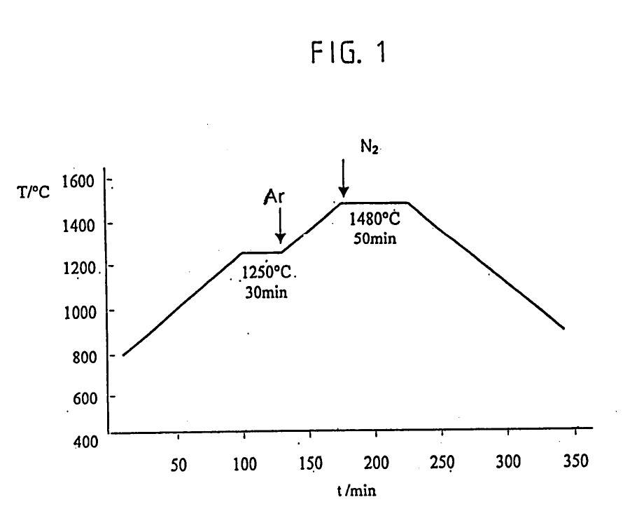

FIG. 1 a sintering profile for the treatment of a sample,

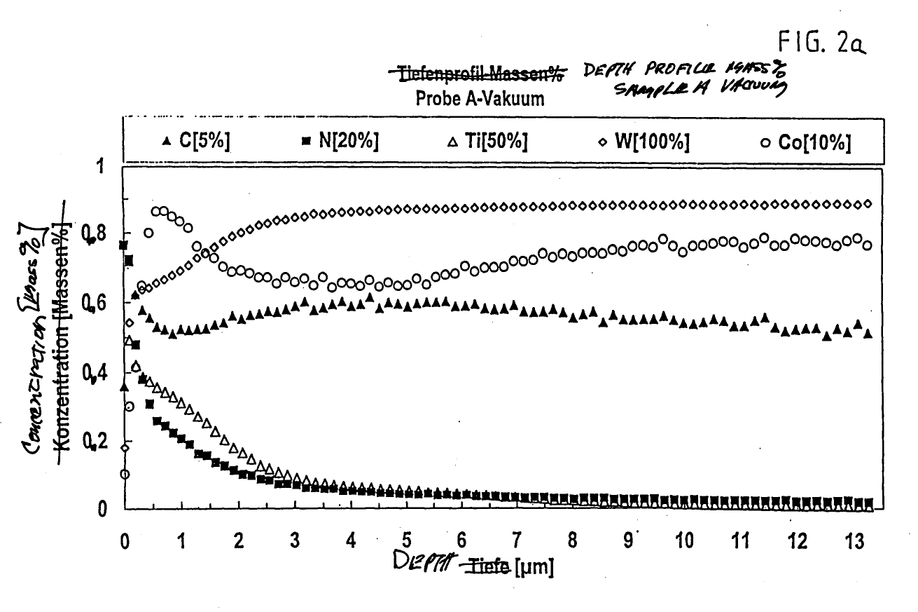

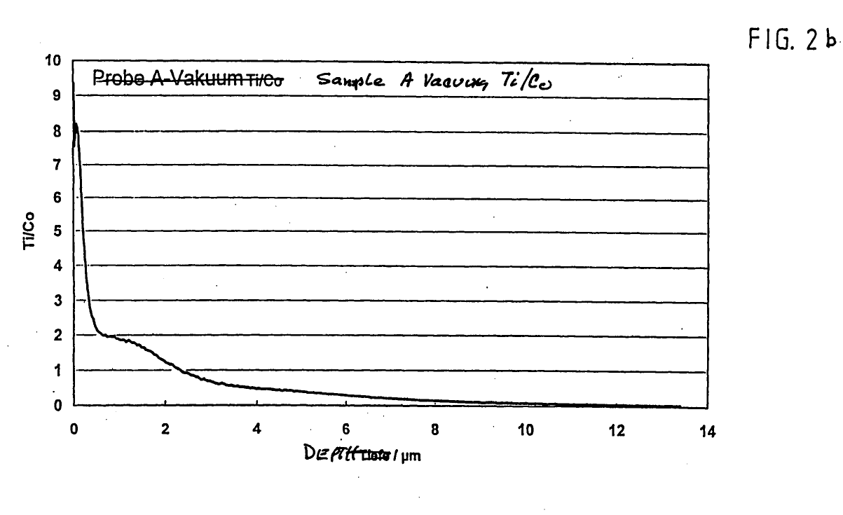

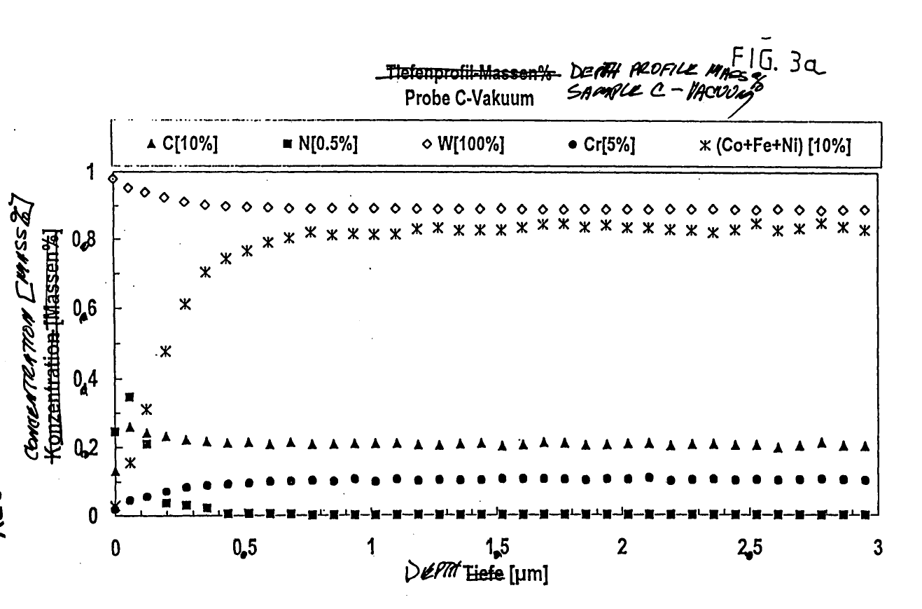

FIG. 2a, b each a semiquantitative GDOS-depth profile of sample A,

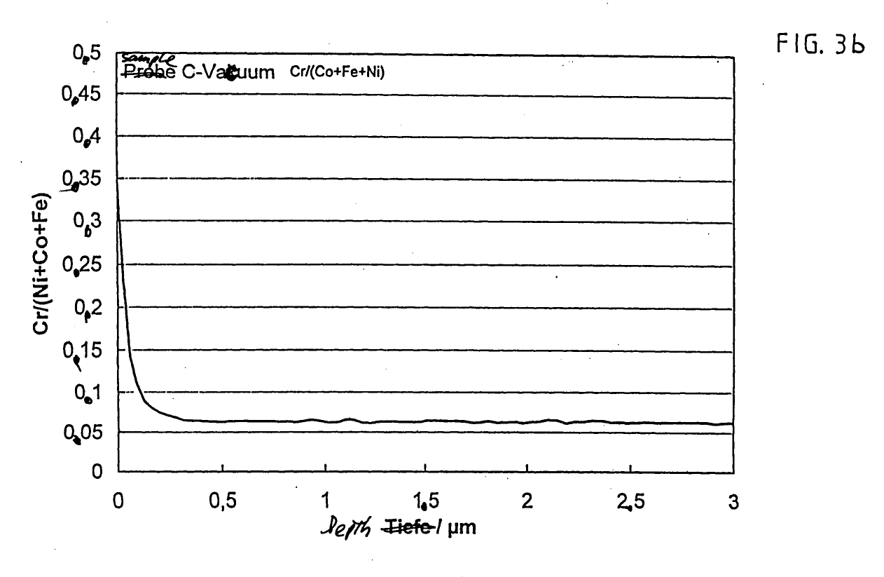

FIG. 3a, b each a semiquantitative GDOS-depth profile of sample C,

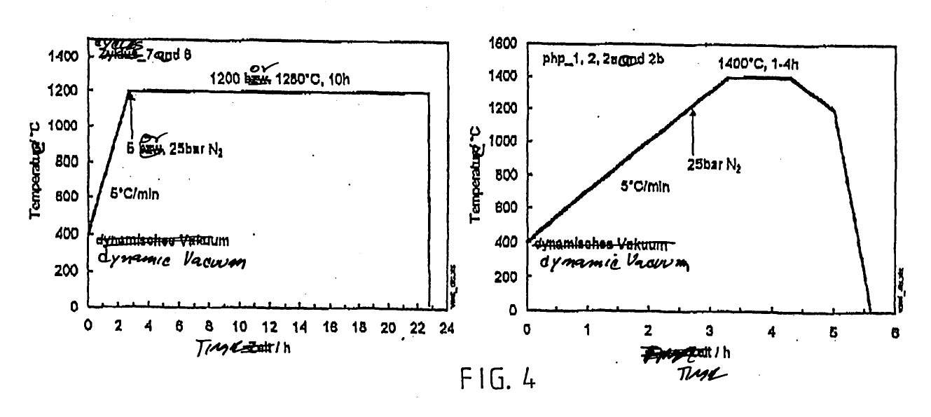

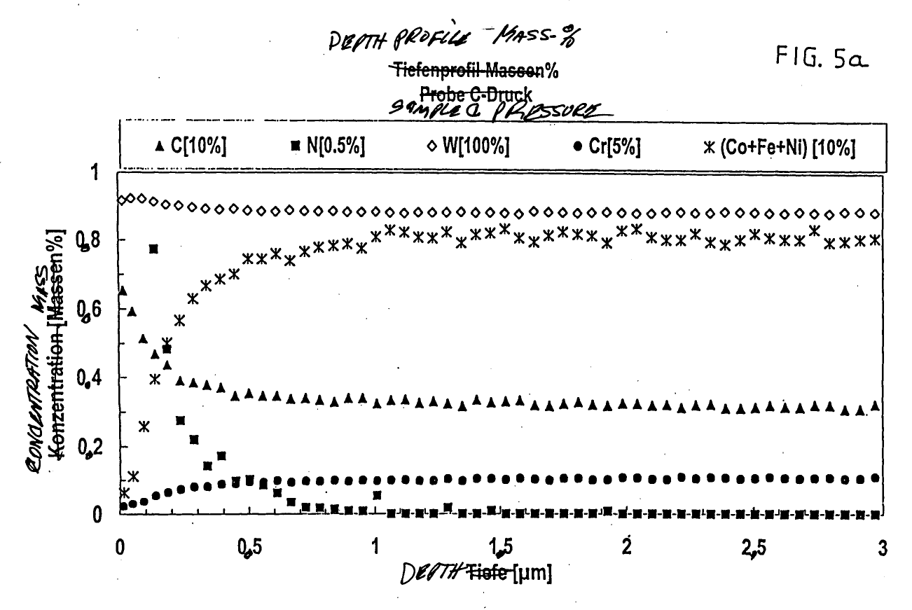

FIG. 4 further sintering profiles and

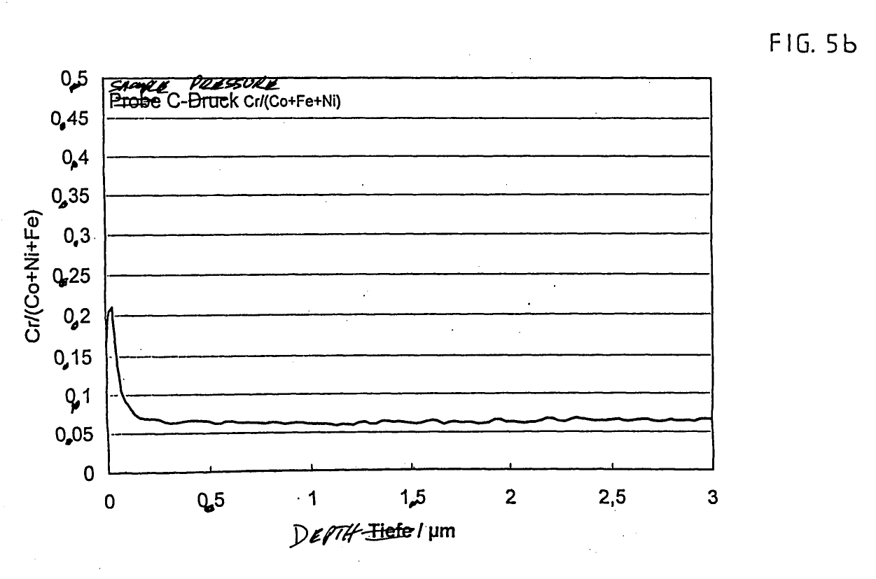

FIG. 5a, b respective semiquantitative GDOS-depth profile of the sample C which is subjected to a treatment in accordance with the sintering profile according to FIG. 4.

Five alloys according to the compositions in the following table are milled in the usual way, mixed and prepressed to a green body which is then subjected to a sintering treatment whose sintering profile can be deduced from FIG. 1.

TABLE 1
Sample Composition

| Sinter body | Composition (Mass %) |
|---|---|
| A | 92% WC, 7.5 Co, 0.5 Ti₂AlC |
| B | 91.75% WC, 0.75% Cr₃C₂, 3.75% Co, 3.75% Ni |
| C | 91.75% WC, 0.75% Cr₃C₂, 4.5% Co, 1.5% Ni, 1.5% |
| | Fe |
| D | 91.75% WC, 0.75% Cr₃C₂, 7.5% Co |
| E | 91.4% WC, 0.75% Cr₃C₂, 0.35% No₂C, 7.5% Co |

The aforementioned alloy A is heated with a heating velocity of 5° C./min initially to 1250° C. This temperature was maintained for about 30 minutes, after which an argon gas atmosphere with a pressure of 5×10³ Pa was established. Simultaneously the heating of the sinter body with a heating speed of 5° C./min was continued and upon reaching for 1480° C., a N₂ pressure of 7×10⁴ Pa was established and maintained even after reaching the sinter temperature of 1480° C. The sintering duration was about 1 hour, whereupon the furnace was shut off.

With the sintering body of sample A, it was established that the nitrogen treatment affected the regions close to the surface to a depth of up to 1 μm such that there the binder phase, that is the sum of the binder metals, was depleted and a significant enrichment of the hard material phase at the surface and in regions near the surface was produced (see FIG. 2a). This can be established both by metalographic transverse grinding and purely optically from the color change. FIG. 2b shows the ratio of the dopant Ti to the binder metal Co. One can see that the doping element with respect to the binder metal sharply is enriched toward the surface substrate body and that at the surface a very thin Ti(C,N) layer is provided.

As a further example of the effect of modifying the boundary zone FIG. 3a shows a semiquantitative GDOS depth profile.

One can clearly see that the sum of the binder metals (Fe, Co, Ni) at the outer surface declines. FIG. 3b shows a clear increase in the ratio Cr/(Co+Fe+Ni) toward the surface to a small penetration depth (about 0.1 μm). This means that in the binder in the graded boundary zone which is influenced by nitrogen, the Cr content in the binder phase relative to the other elements by comparison with the interior regions which are not influenced by the nitrogen, is increased. The nitrogen content increases sharply in the binder zone toward the surface while the carbon and tungsten content increase slightly.

Samples of the type A to F according to table 1 are subjected to different annealing and sintering operations with increased nitrogen pressure according to table 2.

TABLE 2
Sintering profile for the samples A to F of Table 1.

| Sample | Sinter Profile |
|---|---|
| B | Cycle 7 |
| C | Cycle 7 |
| A | Cycle 7 |
| C | php_1 |
| A | php_1 |
| D | php_2 |
| E | php_2 |
| C | php_2 |
| E | php_2 |
| B | php_2 |
| D | php_2a |
| F | php_2a |
| D | php_2b |
| F | php_2b |

The sintering profiles are given in table 3 and table 4.

TABLE 3
TABULAR DESCRIPTION OF SINTERING PROFILES

| | | | | |
|---|---|---|---|---|
| | p(N₂) | max. | Retention time at | Cooling |
| Pretreatment | bar | Temperature | Temperature h | Conditions |

Cycle 8

| | | | | |
|---|---|---|---|---|
| dynamic | 5 | 1200° C. | 10 | Cooling = 250° C./min |
| vacuum to | | | | |
| max. temperature | | | | |

Cycle 7

| | | | | |
|---|---|---|---|---|
| dynamic | 25 | 1280° C. | 10 | Cooling = 250° C./min |
| vacuum to | | | | |
| max. temperature | | | | |

php_1

| | | | | |
|---|---|---|---|---|
| dynamic | 25 | 1400° C. | 1 | to 1200° C. at |
| vacuum to | | | | 5°/min then |
| max. temperature | | | | cooling = 250° C./min |

php_2

| | | | | |
|---|---|---|---|---|
| dynamic | 25 | 1400° C. | 1 | to 1200° C. at |
| vacuum to | at 1200° C. | | | 5°/min then |
| 1200° C. | | | | cooling = 250° C./min |

php_2a

| | | | | |
|---|---|---|---|---|
| dynamic | 25 | 1400° C. | 2 | to 1200° C. at |
| vacuum to | at 1200° C. | | | 5°/min then |
| 1200° C. | | | | cooling = 250° C./min |

php_2b

| | | | | |
|---|---|---|---|---|
| dynamic | 25 | 1400° C. | 4 | to 1200° C. at |
| vacuum to | at 1200° C. | | | 5°/min then |
| 1200° C. | | | | cooling = 250° C./min |

The semiquantitative GDOS depth profile of sample C is shown in FIG. 5 which indicates the reduction in the sum of binder metal in the region proximal to the surface. The sum of the binder metal has the same characteristic as in the case of thesame type of vacuum sintering. The N proportion and the C proportion is also increased toward the surface as in the case of the alloy C sintered under reduced pressure. FIG. 5b shows a clear increase in Cr/(Co+Ni+Fe) concentration ratio toward the zone proximal to the boundary.

By the choice of the doping elements or their compounds and also by the choice of the nitrogen pressure, the boundary zone of the finished hard metal sinter body, i.e. the zone adjacent the outer surface, can be so modified that not only is their enrichment of the dopant but also the formation of a diffusion layer of nitrides. If for example Cr or a Cr compound is used for doping, a vacuum sintering with later N₂ gas phase adjustment under low pressure (<105 Pa) there is no chromium nitride layer or chromium nitride enrichment since chromium nitride does not form at reduced nitrogen pressure. By contrast, with a doping using a vanadium containing or titanium containing phase, there is a formation of TiN or Va or of Ti(N,C) or V(C,N) under the same conditions as described because vanadium nitride or carbonitride for example form even with reduced nitrogen pressure.

1. A hard metal substrate body comprised of a WC hard material phase and a binder phase of 3 to 25 mass % which apart from at least one of the binder metals Fe, Co and/or Ni contains up to 15 mass % of the binder phase dissolved dopant selected from the group comprised of Al, Cr, V, Nb, Ta, Ti, Zr, Hf, characterized in that the percentage proportion of all doping agents in the hard metal is limited to a maximum of 4 mass % in that the proportion of a cubic phase in the hard metal is less than 4 volume % and in that the binder metal content in a hard metal-substrate body boundary zone falls from up to 1 μm, preferably up to 0.5 μm to less than 0.5 times the binder content in the substrate body interior.

2. The hard metal substrate body according to claim 1 characterized in that the concentration of the binder phase falls gradually toward the substrate body surface and the concentration of the dopant gradually increases in a corresponding manner.

3. The hard metal substrate body according to claim 1 characterized in that the grain size of the WC is ≦1.5 μm whereby the WC fine hard metal (grain size ≦0.8 μm) and/or with WC ultrafine grain hard metal (grain size ≦0.5 μm), preferably contain Cr, V and/or Ta as dopant.

4. The hard metal substrate body characterized in that at lest one layer is applied to the substrate body surface, the layer being comprised of a carbide, nitride and/or carbonitride of Ti, Zr and/or Hf and/or of Al₂O₃, HfO₂, ZrO₂, oxides, amorphous carbon, diamond, cubic boron nitride, carbon nitride (CNₓ) or another compound of at least one of the elements B, C, N and/or O.

5. The hard metal substrate body according to claim 1 characterized in that in the boundary zone close to the surface there is an enrichment with nitride or carbonitride of the metal dopant.

6. A method of producing a hard metal substrate body according to claim 1 in which the starting mixture is preheated powder metallurgically is prepressed to a green body and then in an atmosphere of a furnace is heated and sintered, characterized in that in the heating phase, after reaching the eutectic, but no later than reaching the sintering temperature the vacuum or inert gas atmosphere is replaced with a N₂ atmosphere with a N₂ pressure of ≦10⁵ Pa and is maintained at least until the sintering temperature is reached.

7. The method of making a hard metal substrate body according to claim 1 in which the starting mixture is powder metallurgically treated and is pressed to a green body and finally heated in an atmosphere of a furnace and sintered, characterized in that after finish sintering or optionally in a final treatment above the eutectic temperature, the sintered body is maintained in a N₂ atmosphere under a pressure (p) of 10⁵ Pa <p<10⁷ Pa for at least 10 minutes.

8. The method according to claim 6 characterized in that the nitrogen atmosphere is established by introducing precursors that is N-containing gases whereby the nitrogen is formed in situ in the gas atmosphere.

9. The method according to claim 6 characterized in that the body is heated up to 1250° C. during the heating phase and this temperature is held for at least 20 minutes, preferably more than 1 hour, before the heating up is continued to the sintering temperature.

10. The method according to claim 6 characterized in that initially in the heating up phase at about 1200° C. the previously existing vacuum is replaced by an inert gas atmosphere, preferably with a pressure of 10³ Pa to 10⁴ Pa and only upon reaching the sintering temperature is a nitrogen containing atmosphere established with a higher pressure, preferably ≧10⁴ Pa.

11. The method according to claim 6 characterized in that the heating up rate and the cooling down rate amounts to up to 10° C./min, preferably between 2° C./min and 5° C./min.

12. The method according to claim 6 characterized in that the starting mixture contains up to 15 mass % of the binder phase additional carbides, nitrides, carbonitrides of the elements of Group IVa or VIa of the periodic system or Al or complex carbides, complex nitrides and/or complex carbonitrides of the form Ti₂AlC, Ti₂AlN, Cr₂AlN, Cr₂AlC.
